(19) United States
(12) Patent Application Publication
(10) Pub. No.: US 2006/0105550 A1
(43) Pub. Date: May 18, 2006

(54) Method of depositing material on a substrate for a device

(76) Inventor: Manish Sharma, Sunnyvale, CA (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 10/990,802

(22) Filed: Nov. 17, 2004

(51) Int. Cl. H01L 21/20

(52) U.S. Cl. 438/479

(57) ABSTRACT

The present invention provides a method of depositing material on a substrate for a device. The method includes providing the substrate having a deformable surface. The method also includes imprinting a structure into the deformable surface in a manner such that a base surface and at least one projection is formed that projects from the base surface and that overhangs a portion of the base surface. Further, the method includes directing a material flux to the substrate so that the at least one projection interferes with the material flux. In addition, the method includes controlling a masking effect of the at least one projection by selecting a flux direction relative to the substrate.

### FIELD OF THE INVENTION

The present invention relates generally to a method of depositing material on a substrate for a device. The present invention relates particularly, though not exclusively, to a method of depositing material on a substrate for an electronic device.

### BACKGROUND OF THE INVENTION

Electronic devices, such as integrated electronic devices, typically are formed on a substrate, such as a silicon substrate. Such devices often include layered structures having a plurality of insulating, semi-conducting and electrically conducting layers. Such layers often are narrow strips that are formed on top of each other or adjacent to each other and that may be in electrical communication.

Formation of each layer typically involves a range of processing steps. Initially a mask is fabricated that has a structure which is related to a structure of the layer to be fabricated. The substrate is then coated with the layer material and subsequently coated with a photo resist. The photo resist is then exposed to radiation and the mask is used to block off areas of photo resist that should not be exposed. After exposure etching is used to etch selected region through the photo resist and through the underlying layer so that the underlying layer has the desired structure.

For example, a device may include a layered structure having layers which are disposed in a pre-determined manner relative to each other and that may be aligned. For the fabrication of such a layered structure separate masking, exposure and etching processes are required for each layer. This is a cumbersome procedure and there is a need for an alternative method.

### SUMMARY OF THE INVENTION

Briefly, an embodiment of the present invention provides a method of depositing material on a substrate for a device. The method includes providing the substrate having a deformable surface. The method also includes imprinting a structure into the deformable surface in a manner such that a base surface and at least one projection is formed that projects from the base surface and that overhangs a portion of the base surface. Further, the method includes directing a material flux to the substrate so that the at least one projection interferes with the material flux. In addition, the method includes controlling a masking effect of the at least one projection by selecting a flux direction relative to the substrate.

The invention will be more fully understood from the following description of embodiments of the invention. The description is provided with reference to the accompanying drawings.

### BRIEF DESCRIPTION OF THE DRAWINGS

FIG. 1 is a flow chart illustrating a method of depositing material on a substrate for a device according to an embodiment of the present invention;

FIGS. 2 (a) to 2 (e) illustrate processing steps of the method of depositing material on a substrate according to an embodiment of the present invention;

FIG. 3 shows a side view of a layered structure on a substrate according to a further embodiment of the present invention;

FIG. 4 shows a side view of another layered structure on a substrate according to yet another embodiment of the present invention;

FIGS. 5 and 6 show side views of variations of stamps according to further embodiments of the present invention.

### DETAILED DESCRIPTION OF EMBODIMENTS

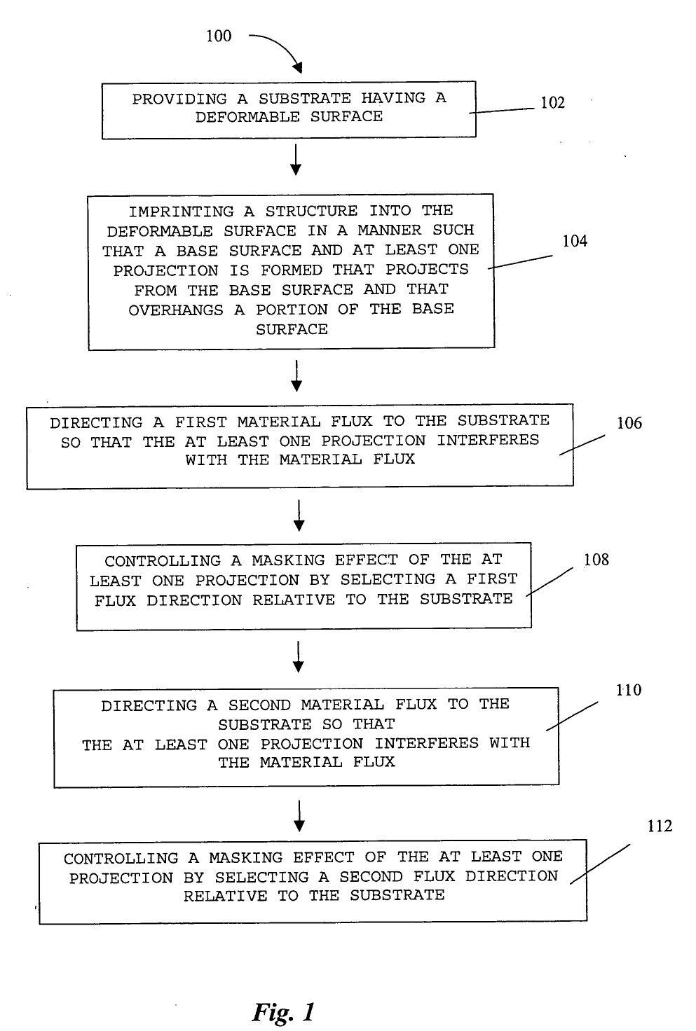

Referring initially to FIG. 1, a method of depositing material on a substrate for a device is now described. The method 100 includes the initial step 102 of providing a substrate having a deformable surface. For example, the substrate may include a hard base coated with the deformable material. Alternatively, the base may be flexible such as a base formed from a flexible polymeric material or the entire substrate may be formed from the deformable material. A structure is then imprinted into the deformable surface in a manner such that a base surface and projections are formed that project from the base surface (step 104). The structure is imprinted so that each projection overhangs a portion of the base surface.

A first material flux is then directed to the substrate so that the projections interfere with the material flux (step 106). A masking effect of each projection can be controlled by controlling a material flux direction relative to the substrate so that the overhanging projections mask portions of the base surface and no material is deposited in masked areas (step 108).

After a first material layer is deposited, a second material flux may be directed to the substrate so as to form a second material layer (step 110). Again, the masking effect of the projections may be controlled by controlling a direction of the second material flux relative to the substrate (step 112).

For example, the second material flux may be directed to the substrate in a direction that differs from the direction of the first material flux. In this case the second layer may be positioned on the first layer, may partially overlap the first layer or may be positioned adjacent to the first layer. Further, the layers may have aligned edges. In an analogous manner structures having more than two layers may be formed. For example such multi-layered structures may include electrically conductive and semi-conductive layers which may be in electrical communication with each other and which may have aligned edges. Further, the layered structures may include electrically insulating layers to insulate the conductive or semi-conductive layers.

Embodiments of the method 100 therefore have the significant advantage that a multi-layered structure having layers which are disposed relative to each other in a predetermined manner and/or which may have aligned edges may be formed without the need for a separate patterning process for each layer. As the multi-layered structure may be formed on a hard base surface or on a flexible base surface, the method has a wide range of applications.

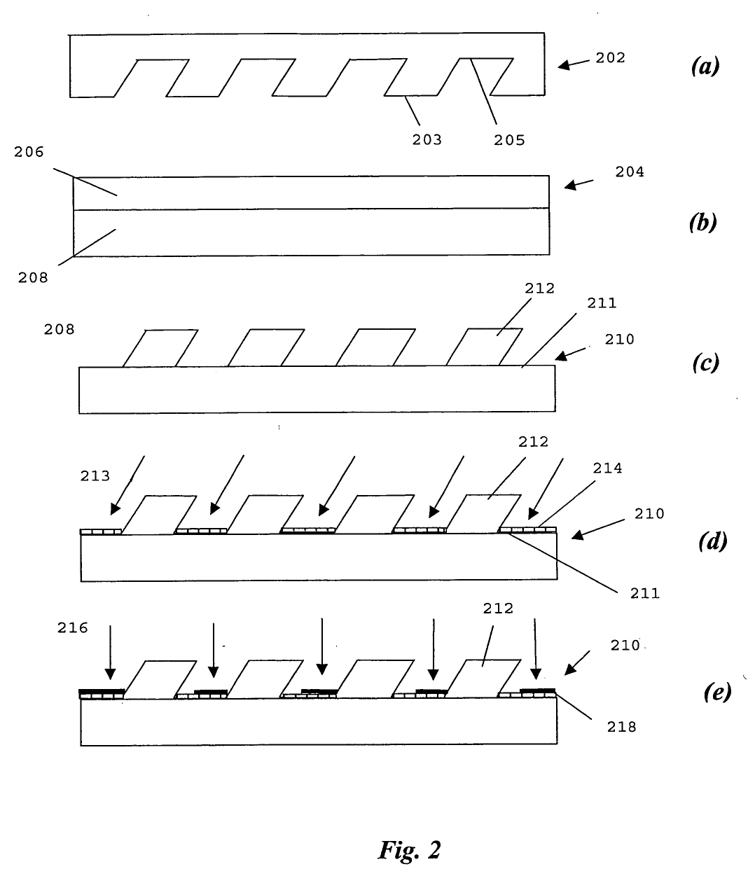

FIG. 2 illustrates steps of the method of depositing material on a substrate for a device in more detail. FIG. 2(a) shows a side view of a stamp 202. The stamp 202 includes projections 203 which project from a surface 205. Each protection 203 overhangs a portion of the surface 205. In this embodiment each projection 203 is elongated along the surface 205 and a void region that has the shape of a channel is defined between adjacent projections 203. In this embodiment the projections 203 are spaced apart by a distance of approximately 10 nm or more. It will be appreciated that in alternative embodiments the projections 203 may have any size or shape such as curved, profiled or round in a direction along the surface 205 and/or in a direction perpendicular to the surface 205. Alternatively, the projections may be arranged in columns and/or rows and may form a pattern. Typically the stamp 202 is composed of a hard material such as a metallic material. In an alternative embodiment of any other suitable material may be used, such as a plastics material.

FIG. 2(b) illustrates a substrate 204 having a deformable surface. In this embodiment the substrate 204 includes a base 208 which is coated with a polymeric material 206. The stamp 202 is moved into the polymeric material 206 so as to deform the polymeric material 206. The polymeric material 206 is then hardened which typically involves heat treatment or UV radiation treatment. The stamp 202 is then removed from the hardened polymeric material 206 and a substrate having projections is formed which is shown in FIG. 2 (c). The base 208 may be formed from a hard material, such as silicon, or may also be formed from a flexible material, such as a polymeric material. The base 208 and the deformable coating may also be integrally formed from the same deformable material. In this case stamping typically is conducted on a hard surface from which the stamped substrate is removed after the polymeric material is hardened.

The structure 210 includes projections 212 which are composed of the hardened polymeric material and which have a shape and size that corresponds to that of the void regions defined between adjacent projections 203 of the stamp 202. Each projection 212 projects from a base surface 211 and overhangs a portion of the base surface 211. In this embodiment the projections 212 are elongated along the base 208 and adjacent projections form sidewalls of a channel positioned between the adjacent projections. It will be appreciated that the projections 212 may have any size or shape including shapes having straight edges and also including curved shapes, profiled or round shapes (in a direction along the base surface 210 and/or in a direction perpendicular to the base surface 210).

FIG. 2(d) illustrates a further processing step. A first material flux 213 is directed to the substrate. In this embodiment a direction of the first material flux 213 is selected so that the first material flux 213 deposits a layer 214 on the entire base surface area 211 between projections 212.

FIG. 2(e) illustrates a subsequent processing steps according to an embodiment in which a second material flux 216 is directed to the base surface 211. In this example, the flux direction is selected so that the overhanging projections 212 mask a portion of the base surface 211 coated with the layer 214. Consequently flux material will not be deposited over the entire base surface 211 but only a selected portion of the base surface 211 will be coated with the second material. In this embodiment, the first layer 214 and the formed second layer 218 have edges along the projections 212 which are aligned. After formation of the layers 214 and 218 the projections 212 are etched away using a dry etching process or a chemical etching process commonly used in the art. For example, the dry etching process may be an Ar—O₂ plasma etching process. A suitable wet etching process includes treatment with a solvent which dissolves the projections 212. In a variation of this embodiment the projections 212 may not be removed and may form a part of the device.

In the same manner, a large number of layers may be deposited. Each of the deposited layers may be deposited using a different material flux direction so that the layers may have a plurality of aligned edges. Typically adjacent layers are formed from different materials.

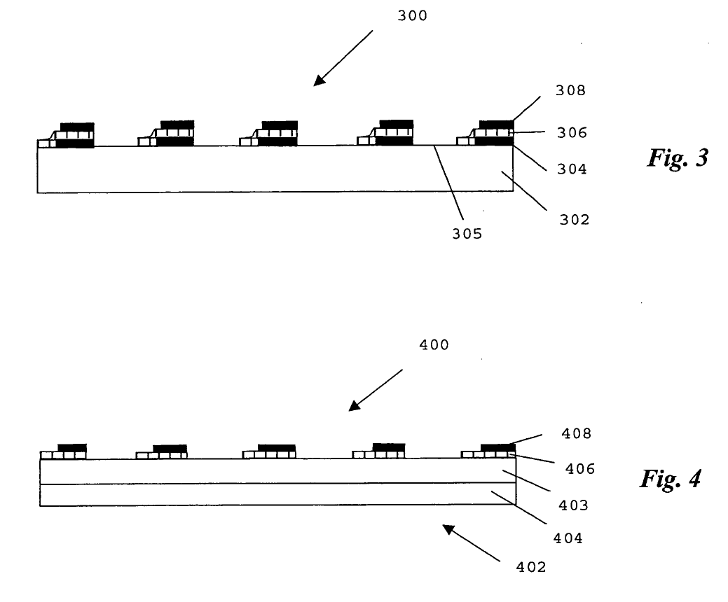

FIG. 3 shows a side view of a layered structure formed by the process illustrated in FIGS. 1 and 2. In this embodiment the structure 300 includes a base 302 which is a silicon wafer. For example, the base 302 may also be composed of another semi-conducting material, glass, a plastics material or a metal. In this embodiment the layered structure 300 includes a plurality of stacked layers positioned on the base 302. Each layer of each stack was fabricated using the method as illustrated in FIGS. 1 and 2. For fabrication of the layered structure 300 projections of the same type as projections 212 shown in FIG. 2 were positioned on the base layer 302. The stacked layers of the layered structure 300 were fabricating between the projections and using the projections to control the masking effect as discussed above. After deposition of the layers the projections where etched away using the same etching process as described above.

In this embodiment, each stack of layers includes an under-layer 304 and an over-layer 308. Further, layer 306 is an under-layer for the layer 308 and an over-layer for the layer 304. The layer 304 is deposited on the base surface 305 and the layer 306 covers and overlaps the layer 304. The layer 304 terminates under the layer 306 and the layer 308 terminates over the layer 306. In this embodiment the layers 304, 306 and 308 are formed from different materials such as semi-conducting, electrically conducting or insulating materials. In this example the layers 304, 306 and 308 have aligned edges. For formation of each layer 304, 306 and 308 a different material flux direction was chosen so that the layers have edges which are aligned and disposed in a pre-determined manner.

FIG. 4 shows a side view of another example of a structure having a multi-layer structure produced by the method illustrated in FIGS. 1 and 2. In this embodiment the structure 400 includes a base 402 and a plurality of stacked layers 406 and 408. Between each stack a projection of the type of projection 212 shown in FIG. 2 was positioned. The base 402 includes a first base portion 403 and a second base portion 404. In this embodiment the second base portion 404 is composed of a hard material, such as a silicon wafer, and the first base portion 403 is composed of the same hardened polymeric material as projections 212. To form the first base portion 403 and projections for deposition of the layer stacks, a stamp such as stamp 202 shown in FIG. 2 was moved into the initially deformable polymeric material of the base first portion 403 in a manner such not all deformable polymeric material was removed between tips of the projections of the stamp and the second base surface portion 404.

In this embodiment the layer 406 was deposited on the first base portion 403 and the layer 408 was deposited on the layer 404 in a manner so that layer 408 terminates over layer 406. Again, this was achieved by controlling the directions of the respective material fluxes. The layers 406 and 408 have aligned edges which are disposed parallel to each other.

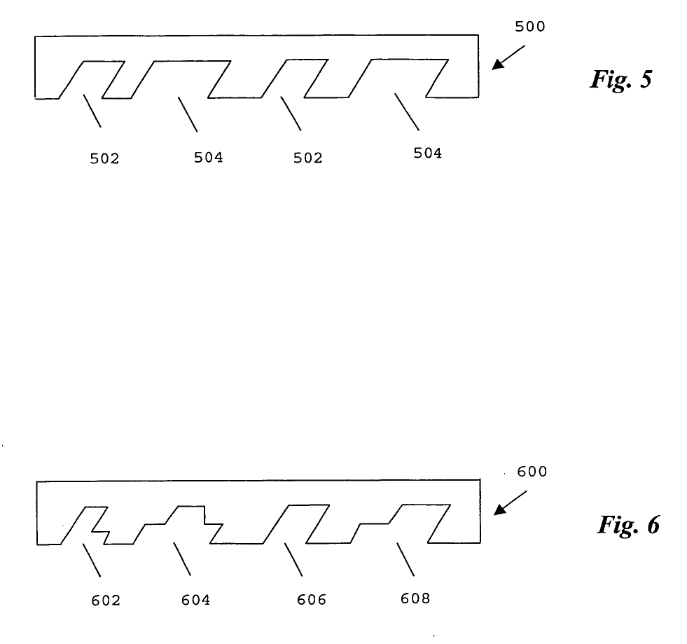

FIGS. 5 and 6 show variations of stamps that may be used for the methods as illustrated in FIGS. 1 and 2. Analogous to the method discussed above, the stamps 500 and 600 are used to from projections in a deformable material such as the material 206 shown in FIG. 2. Stamp 500 includes void regions 502 and 504. The void regions 502 and 504 have a shape that corresponds to the projections that may be formed using the stamp 500. In this embodiment, the projections 502 and 504 have different widths.

Stamp 600 shown in FIG. 6 includes void regions 602, 604, 606 and 608. In this embodiment each void region 602 to 608 has a different shape and therefore each projection that may be formed using the stamp 600 has a different shape. In general, the stamps 202, 500 or 600 may have any from of void areas that allow the void regions to be at least partially, typically fully, filled with the deformable material during the stamping process as described above.

Although the invention has been described with reference to particular examples, it will be appreciated by those skilled in the art that the invention may be embodied in many other forms. For example, it is to be appreciated that the layers that may be deposited with the method as described above maybe of any shape. Further, the layers may include elongated strips and different layers may cross each other. Alternatively, the layers may be curved or may include corners.

For material deposition any suitable source may be used that results in a masking effect of the projections and therefore has at least some directionality For example, the material fluxes may be generated by sputtering or evaporating metal films, dielectric films, or may be generated by electrodepositing or electroplating films.

The device typically is an electrical device such as an integrated electronic device. For example, the layers may have thicknesses and/or widths which are of the order of a few ten micrometres or smaller such as 10-1000 nm. Alternatively, the device may be an optical device such as an integrated optical device.

1. A method of depositing material on a substrate for a device, the method comprising:
providing the substrate having a deformable surface;
imprinting a structure into the deformable surface in a manner such that a base surface and at least one projection is formed that projects from the base surface and that overhangs a pardon of the base surface;
directing a material flux to the substrate so that the at least one projection interferes with the material flux such that the at least one projection overhanging the portion of base surface masks the portion of the base surface to prevent the material flux from being deposited on the masked portion of the base surface when the material flux is deposited on the base surface; and
controlling a masking effect of the at least one projection by selecting a flux direction relative to the substrate.

2. The method of claim 1 wherein:
the device is an electronic device.

3. The method of claim 1 wherein:
the substrate comprises a deformable coating on a hard base surface.

4. The method of claim 1 wherein:
the substrate comprises a deformable coating on a flexible base surface.

5. The method of claim 1 wherein:
the base surface comprises a polymeric material.

6. The method of claim 1 wherein:
the step of directing a material flux to the substrate comprises directing a plurality of material fluxes to the substrate.

7. The method of claim 6 wherein:
the material fluxes are directed to the substrate in a sequential manner so that a layered structure is formed which comprises a plurality of layers.

8. The method of claim 7 wherein:
the step of controlling a masking effect of the at least one projection comprises directing the material fluxes to the substrate in directions that differ from each other.

9. The method of claim 8 wherein:
the material flux deposits material in an area that overlaps a layer so that at least one over-layer is formed.

10. The method of claim 9 wherein:
the at least one over-layer terminates over at least one under-layer.

11. The method of claim 9 wherein:
at least one under-layer terminates below at least one under-layer.

12. The method of claim 10 wherein:
at least a portion of the at least one over-layer and at least a portion of the at least one under-layer have an edge portion that is substantially parallel.

13. The method of claim 11 wherein:
at least a portion of the at least one over-layer and at least a portion of the at least one under-layer have an edge portion that is substantially parallel.

14. The method of claim 7 wherein:
adjacent layers arc composed of different materials.

15. The method of claim 7 wherein:
at least one of the layers comprise an electrically conductive material.

16. The method of claim 7 wherein:
at least one of the layers comprises a semi-conductive material.

17. (canceled)

18. The method of claim 7 wherein:
at least one of the layers comprises an electrically insulating material.

19. The method of claims 1 wherein:
the step of imprinting a structure into the deformable surface is performed in a manner such that a base surface and a plurality of projections arc formed that project from the base surface and that overhang a portion of the base surface.

20. The method of claim 19 wherein:
the projections form a pattern.

21. The method of claim 19 wherein:
the projections arc disposed in rows.

22. The method of claim 21 wherein:
adjacent projections from sidewalls of a channel.

23. The method of claim 19 wherein:
the projections are elongate and extend along a portion of the substrate.

24. A method of fabricating an electronic device, the method comprising the steps of;
providing a substrate having a deformable surface;
imprinting a structure into the deformable surface in a manner such that a bas surface and at least one projection is formed flat projects from the base surface and that overhangs a portion of the base surface;
directing a material flux to the substrate so that the at least one projection interferes with the material flux such that the at least one projection overhanging the portion of base surface masks the portion of the base surface to prevent the material flux from being deposited on the masked portion of the base surface when the material flux is deposited on the base surface: and
forming electronic components associated with the deposited material.

25. A method of fabricating an electronic circuitry having aligned layers, the method comprising the steps of:
providing a substrate having a deformable surface;
imprinting a structure into the deformable surface in a manner such that a base surface and at least one projection is formed tat projects from the base surface and that overhangs a portion of the base surface;
directing a first material flux to the substrate to deposit a material on the base surface, the at least one projection masking a first portion of the base surface such that the overhang of the projection prevents the first material flux from being deposited on at least a portion of the masked portion of the base surface when the first material flux is deposited on the base surface; and thereafter
directing a second material flux to the substrate to deposit a material on the base surface, the second material flux being directed to the substrate in a direction that is different to that of the first material flux, the at least one projection masking a second portion of the base surface c that the overhung of the projection prevents the second material flux from being deposited on at least a portion of the masked portion of the base surface when the second material flux is deposited on the base surface;
wherein material layers are formed having aligned terminations.

26. (canceled)
